(19) United States
(12) Patent Application Publication
(10) Pub. No.: US 2026/0348892 A1
(43) Pub. Date: Nov. 5, 2026

(54) SOLID IMMERSION LENS, METHOD FOR PRODUCING A SOLID IMMERSION LENS, AND DEVICE AND METHOD FOR A SPATIALLY RESOLVED MEASUREMENT OF A PHYSICAL VARIABLE OF A SAMPLE USING THE SOLID IMMERSION LENS

(71) Applicant: QuantumDiamonds GmbH, München (DE)

(72) Inventors: Dominik Benjamin Bucher, München (DE); Robin Derek Allert, München (DE); Martin Schalk, München (DE)

(21) Appl. No.: 19/488,536

(22) PCT Filed: May 29, 2024
(86) PCT No.: PCT/DE2024/100493

§ 371 Date: Nov. 26, 2025

(30) Foreign Application Priority Data
May 31, 2023 (DE) 10 2023 114 224.0

(51) Int. Cl. G01N 24/10; G01R 33/032; G01R 33/26

(52) U.S. Cl. CPC G01N 24/10; G01R 33/032; G01R 33/26

(57) ABSTRACT

The invention relates to a device for a spatially resolved measurement of a physical variable of a sample (12), said device comprising a solid immersion lens (14) with a plurality of solid-state quantum sensors (30), a light source (16) for illuminating the solid-state quantum sensors (30), and a wide-field microscope (11) for imaging the solid-state quantum sensors p (30).

The invention relates to a solid immersion lens for a spatially resolved measurement of a physical variable of a sample. The solid immersion lens comprises a base body, a sensor layer configured to be in contact with the sample, and a plurality of solid-state quantum sensors.

The invention further relates to a method for producing a solid immersion lens which comprises solid-state quantum sensors.

Furthermore, the invention relates to a device and to a method for a spatially resolved measurement of a physical variable of a sample, which comprise a solid immersion lens with a plurality of solid-state quantum sensors.

The spatially resolved measurement of magnetic fields is an essential tool for physics and the life sciences. The applications range from biomagnetism measurements to understanding exotic spin behavior in two-dimensional materials. Quantum sensors in solids, such as the nitrogen vacancy center (NV center) in diamonds, have shown extraordinary potential in recent years to revolutionize sensor-based technologies. The areas of application range from biomarker detection in medicine, to GPS-deficient navigation, or to chemical analysis. All these applications require the highest possible sensitivity for commercial success.

A possible process for the fabrication of macroscopic NV-doped SILs was described in Siyushev, P. et al. Monolithic diamond optics for single photon detection. Appl. Phys. Lett. 97, 241902 (2010). This process is also disclosed in WO 2012/016977 A2. Here, a solid immersion lens (SIL) made of diamonds was produced as follows: The homoepitaxial chemical vapor deposition (CVD) of diamonds was carried out with a selected high-pressure and high-temperature diamond that was processed before growth to minimize the dislocation density in the CVD diamond. Subsequently, a two-stage chemical process was applied to produce a CVD layer with a total thickness of approximately 2.3 mm, with the first layer containing ~0.2 ppm substitution nitrogen. The final layer, with a thickness of ~0.6 mm, was produced with a significantly reduced nitrogen concentration of <5 ppb to reduce the number of native NV defects. Two different nitrogen conditions were used, as it was assumed that the first, more highly doped nitrogen layer would reduce the degree of deformation in the CVD layer before the second, thinner but purer layer grew. The SIL was subsequently fabricated from this CVD diamond sample, with the flat surface consisting of the high-purity layer (sensor layer) aligned along a <100>, <110> or <111> crystal axis. A SIL with a radius of 1.0 mm was produced by combining laser and mechanical processing steps, with a flatness better than 10 nm (rms) as measured by the atomic force microscope.

The object of the invention was to provide an improved measurement of a physical variable of a sample.

This object is achieved by the subject matter of the independent claims. The dependent claims describe optional embodiments.

In general, the present invention describes a new idea for high- or super-resolution imaging of a physical variable (for example, a magnetic field) using quantum sensors in solid immersion lenses, which achieves high spatial resolution while maintaining a wide field of view. A resolution of up to 60 nm, for example from 60 nm to 145 nm, can be achieved with the invention.

A solid immersion lens is provided for a spatially resolved measurement of one or more physical variables, optionally a magnetic field, of a sample. The measurement of several physical variables can be performed simultaneously, for example by using different types of solid-state quantum sensors. Optionally, solid-state quantum sensors can be provided in the solid immersion lens, each responding to a different physical variable.

The solid immersion lens comprises a base body, a sensor layer configured to be in contact with the sample, and a plurality of solid-state quantum sensors. The solid-state quantum sensors are configured to absorb and/or emit light, particularly in one or more wavelength ranges, differently at the location of the respective solid-state quantum sensor, depending on the physical variable to be measured. The density of solid-state quantum sensors in the sensor layer is greater than the density of solid-state quantum sensors in the base body.

A method for producing a (macroscopic) solid immersion lens incorporating solid-state quantum sensors comprises the steps of: producing a base body of the solid immersion lens with a first density of solid-state quantum sensors and applying or growing a sensor layer onto the base body, wherein the sensor layer has a second density of solid-state quantum sensors that is greater than the first density.

A device configured for a spatially resolved measurement of a physical variable, optionally a magnetic field, of a sample comprises a solid immersion lens with a plurality of solid-state quantum sensors, optionally as described herein, a light source for illuminating the solid-state quantum sensors, and a wide-field microscope for imaging the solid-state quantum sensors.

A method for spatially resolved measurement of a physical variable, optionally a magnetic field, of a sample comprises the steps of: placing a solid immersion lens with a plurality of solid-state quantum sensors, optionally as described herein, imaging the solid-body quantum sensors using wide-field microscopy, and determining the locally resolved physical variables, optionally the magnetic field, using the imaging of the solid-state quantum sensors.

The advantage of the invention is that the solid-state quantum sensors can be imaged using wide-field microscopy, i.e., using a wide-field microscope. This allows for a simpler design of the microscope or the imaging, as there is no need to use a confocal microscope or similar microscopes that require increased construction effort. Furthermore, all solid-state quantum sensors can be imaged simultaneously, so that, for example, a spatially resolved measurement of the physical size of the sample can be carried out faster. This can be helpful when the physical variable to be measured fluctuates rapidly (e.g., magnetic and/or electric fields with high frequencies) and yet a high spatial resolution is desired. High spatial resolution can still be achieved by using a solid immersion lens.

The wide-field microscope can also be understood as a reflected-light microscope. The beam path of the wide-field microscope cannot have a diaphragm (also referred to as a pinhole) that serves to select a layer along the z-axis or optical axis of the image, as is common in confocal microscopy. This simplifies the design and/or increases the light yield.

The solid immersion lens is characterized by the fact that these solid-state quantum sensors are essentially located only in the sensor layer, and the base body is essentially free of solid-state quantum sensors. This enables the use of wide-field microscopy, since solid-state quantum sensors in the base body, as is common in the prior art, do not affect the imaging of the solid-state quantum sensors. In other words, the absence of solid-state quantum sensors in the base body allows the imaging of the solid-state quantum sensors in the sensor layer using wide-field microscopy, since there is no superposition of signals from the sensor layer with signals from the base body. Therefore, the imaging of the solid-state quantum sensors of the solid immersion lens requires no or only a low spatial resolution in a direction perpendicular to the extent of the sample (i.e., perpendicular to the extent of the sensor layer). The sensitivity of solid-state quantum sensors in diamonds can be increased by an order of magnitude by shaping the substrate material (e.g., a base diamond) into a solid immersion lens (SIL).

Solid-state quantum sensors, such as the nitrogen vacancy center (NV center) in diamond, are a leading modality for sensitive, spatially resolved imaging of microscopic magnetic fields or other physical variables (such as temperature or temperature distribution and/or electric fields) with a large field of view. Solid-state quantum sensors operate under a wide variety of conditions, from low temperatures to well above room temperature, and can be used as broadband detectors (e.g., for slowly fluctuating magnetic fields and/or electric fields) or as narrowband detectors for electric and/or magnetic fields in a wide frequency range from nearly static (DC) to GHz. Furthermore, a complete vector magnetic field (or a vector field of another physical variable) can be measured by utilizing the distribution of the orientations of the solid-state quantum sensors along the four crystallographic directions of the solid immersion lens.

The sensitivity (e.g., for magnetic fields, electric fields, and/or temperature distributions) and the spatial resolution are determined by the number of solid-state quantum sensors in the measurement volume, the resonance linewidth, the resonance spin-state fluorescence contrast, and the collected fluorescence intensity of the solid-state quantum sensors. Thanks to various experimental setups and measurement protocols, magnetic field microscopy or other physical variables can be adapted and/or optimized for numerous applications in various research areas using solid-state quantum sensors (for example, with NV diamonds). Although the desired capabilities can vary greatly for each application, typical requirements include good sensitivity (e.g., for magnetic fields, electric fields, and/or temperature distributions) within a defined frequency range, high spatial resolution, a large field of view, quantitative vector magnetometry, a dynamic frequency range, and flexibility with respect to external parameters (such as external electric and magnetic fields and/or temperature during measurement).

Thus, magnetic field microscopy in geosciences and cell biology generally requires high sensitivity to static magnetic fields (DC) and operation at room temperature. In contrast, magnetic field imaging in microelectronics can require magnetic field frequency sensitivity up to the GHz range. All three applications benefit considerably from a higher spatial resolution, which increases the information content, and a wide field of view that enables fast parallel measurements. Today, according to the prior art, a compromise must be found between these two parameters, which enables either a spatial resolution below the diffraction limit using single-point measurements or a wide field of view with diffraction-limited resolution.

The invention represents a new approach to measuring magnetic fields or other physical variables, with which a spatial resolution below the conventional diffraction limit (super resolution) can be achieved and/or in which the field of view can be several tens of micrometers in size. This is achieved by using a solid immersion lens material with a high refractive index. This may mean that no image below the diffraction limit is achieved, but the diffraction limit is massively reduced, so that improved resolution can be achieved compared to conventional glass lenses.

The field of view has, for example, a radius or side length of 10 μm, 20 μm, 30 μm, 40 μm, 50 μm, 60 μm, 70 μm, 80 μm, 90 μm or 100 μm. The field of view can be, for example, 1000 μm², 2000 μm², 3000 μm², 4000 μm², 5000 μm², 6000 μm², 7000 μm², 8000 μm², 9000 μm² or 10000 μm². This can depend on the size of the solid immersion lens and/or the magnification of the wide-field microscope. Furthermore, the field of view can be enlarged by scanning the sample with the solid immersion lens.

The magnification of the wide-field microscope can be 1×, 10×, 20×, 50×, 100×, 200× or 400×. The magnification can be adjusted, for example, by the size parameters of the solid immersion lens and/or the magnification of the lens. The imaging can be adjusted by varying the parameters magnification, number of pixels, and size of the image sensor.

For example, it is known from the prior art that solid-state quantum sensors can be imaged using scanning tip microscopy. The scanning tip microscopy used for this is based on the use of a sharp microscopic NV diamond tip, which is scanned at a controlled distance of only a few nanometers from a sample. As the tip moves across the surface, the topography and magnetic structures of the sample are recorded, producing images with nanometer resolution. To achieve the best spatial resolution, the NV center is moved very close to the tip of the tip. While the radius of curvature of the tip determines the lateral resolution of the topographic image, the distance between the NV center and the sample surface determines the lateral resolution for the magnetic image. Theoretically, a spatial resolution of 10 nm is possible; in practice, the resolution is more likely to be on the order of 25-50 nm for samples where the tip is as close to the surface as possible. Cover layers, for example, reduce the resolution. Because the tip must be very close to the sample and very stable, the experimental setups are extremely complex, expensive and not easy to handle. The invention solves these problems by using wide-field microscopy to image the solid-state quantum sensors, which provides a similar resolution but allows for faster measurement, since many, optionally all, solid-state quantum sensors in the field of view can be imaged simultaneously. Furthermore, wide-field microscopy is less susceptible to disturbances compared to scanning tip microscopy, for example to vibrations or temperature fluctuations.

Quantum sensors in solids, such as the NV center in diamonds, are usually read out via their spin-state-dependent fluorescence. In this process, the measured signals (e.g., magnetic fields, electric fields, temperature, etc.) are converted into optical signals. This principle can also be applied to the present invention.

The following section explains the basic principles of the invention using magnetic field measurements via NV centers. These principles or considerations apply analogously to the measurement of other physical variables and/or using other solid-state quantum sensors.

One method for measuring an external static magnetic field is the direct evaluation of the Zeeman splitting in an optically detected NV electron spin resonance (ESR) spectrum or in an optically detected magnetic resonance (ODMR). The optimal response of the spin-dependent fluorescence signal (photoluminescence, PL) to a magnetic field is achieved by setting a microwave driver frequency to the maximum slope of a given ESR dip. Assuming an infinitesimal magnetic field variation δB, the change in NV fluorescence is then given by

$$\frac{δ {I}_{0}}{δ B} * δ B * Δ t ,$$

where I₀ is the NV center PL rate, δB is the magnetic field change and Δt is the measurement time. At the same time, the readout noise is dominated by the photon shot noise and is therefore equal

$$\sqrt{\frac{δ {I}_{0}}{δ B}} * δ B * Δ t .$$

Comparing these two expressions yields the photon shot noise-limited magnetic field sensitivity, which is defined as the minimum detectable magnetic field that can be detected at a signal-to-noise ratio of one:

$$η = δ B * \sqrt{Δ t} = \frac{\sqrt{{I}_{0}}}{δ I / δ B}$$

It can be seen that the maximum achievable sensitivity η depends on the measured light intensity—consequently the number of photons per NV center. Consequently, the magnetic field sensitivity can be significantly improved by increasing the detection efficiency of the photoluminescence, which is mainly limited by the collection efficiency of the detection optics.

In conventional detection of NV defects, i.e., with a high numerical aperture microscope objective placed on the diamond surface, the collection efficiency is essentially limited by the high refractive index of diamond (n=2.4), which leads to total internal reflection at the diamond-air interface. Since the critical angle of internal total reflection is approximately θ_c=22.6°, most of the emitted photons remain trapped in the diamond, reducing the amount of light collected by the microscope objectives. To suppress total internal reflection, the NV centers can be embedded in a diamond solid immersion lens (generally: the solid-state quantum sensors in a solid immersion lens). With this geometry, all or most light rays can exit the field of view perpendicular to the surface of the solid immersion lens. This improves the collection efficiency of solid-state quantum sensors by about an order of magnitude.

The solid immersion lens represents an optical lens, optionally a plano-convex converging lens. The solid immersion lens can be a (one-sided) spherically ground lens with positive refractive power.

The solid immersion lens has a sample side and an optical side. The sample side is the side of the solid immersion lens on which the sample is placed, which is in contact with the sample or which is close to the sample. The sample surface can be flat and/or form one or more planes. Furthermore, the sample side can form a cone or a truncated cone. The shape of the sample side can be adapted to the shape of the sample so that the sample side is as close as possible to the sample over its entire extent. The sample side is optionally a side surface of the sensor layer. This allows the solid-state quantum sensors to be positioned as close as possible to the sample. For example, the sensor layer can alternatively or additionally be designed in such a way that the sensor layer is arranged in (direct) proximity to the sample.

The optical side of the solid immersion lens is the side of the solid immersion lens through which light is coupled in to excite the solid-state quantum sensors and/or the light emitted by the solid-state quantum sensors is coupled out of the solid immersion lens. The optical side is therefore the side through which light is passed for imaging the solid-state quantum sensors.

The optical side has a structure or shape chosen such that all or most of the light emitted by the solid-state quantum sensors in the field of view can exit the solid immersion lens through the optical side. For example, the optical side has a convex shape, such as a hemisphere or the shape of a spherical segment. Furthermore, the optical side can have the shape of a Weierstrass lens. The optical side is optionally provided by the base body. This means that the basic body has the properties described above, enabling it to couple out light emitted by the quantum sensors.

The optical side can have a hemisphere radius of 0.1 mm, 0.5 mm, 1 mm, 2 mm or 4 mm. These values can also be the radii for the circular sample side. The position of the center of the hemispherical shape or of a sample side with Weierstrass lens shape can have a tolerance of ±50 μm, ±10 μm, ±5 μm, ±1 μm, ±0.5 μm or ±0.1 μm.

The roughness of the optical side can have a standard deviation of less than 5 μm, less than 1 μm, less than 0.5 μm, less than 0.25 μm, less than 0.05 μm, less than 0.01 μm, or more than 0.001 μm. Furthermore, the optical side can have a tolerance in roundness, a measure of how closely the shape of the optical side in cross-section resembles a semicircle, of less than 10 μm, less than 5 μm, less than 1 μm, less than 0.5 μm, less than 0.1 μm or less than 0.05 μm or more than 0.01 μm.

The sample area is optionally provided partially or completely by the sensor layer. This means that the sample side is a side or side surface of the sensor layer. For example, an exposed side of the sensor layer, i.e., a side of the sensor layer that can be touched from the outside, is the sample side or forms part of it. This means that the solid-state quantum sensors are located near or directly on an outside of the solid immersion lens that is in contact with or near the sample. This allows the solid-state quantum sensors to be positioned close to the sample (or the sample close to the solid-state quantum sensors), so that the physical variables to be determined can be measured better, since there are no or only minor losses or attenuations due to the material of the solid immersion lens.

The sample side can have a radius tolerance of ±100 μm, ±50 μm, ±10 μm, ±5 μm, ±1 μm or ±0.5 μm. The roughness of the sample side can have a standard deviation of less than 100 nm, less than 50 nm, less than 10 nm, less than 5 nm, less than 1 μm, less than 0.1 nm less than 0.01 nm.

The solid immersion lens can be a one-piece component, meaning that the base body and the sensor layer form a single optical component. For example, the sensor layer can be grown onto the base body. It is also possible for the sensor layer to be applied to the base body. Optionally, no optical refraction occurs between the base body and the sensor layer. For example, the refractive index of the sensor layer is identical or substantially equal to the refractive index of the base body, where substantially equal means a deviation of less than 5%, less than 1%, less than 0.5%, less than 0.1%, less than 0.05%, or less than 0.01%, or more than 0.001%. This can be achieved by making the base body and the sensor layer from the same material, whereby the solid-state quantum sensors, due to their low density, do not affect or only minimally affect the refractive index of either the base body or the sensor layer.

The solid-state quantum sensors are optionally only present in the sensor layer and not in the base body. This can be achieved, for example, by incorporating, doping, or implanting the solid-state quantum sensors only in the sensor layer and not in the base body. For example, the base body and the sensor layer can consist of a single-crystal material, with the solid-state quantum sensors being implanted or incorporated during the growth process only in the sensor layer. This means that, apart from deviations in the single-crystal structure (for example, artifacts in the growth process), no solid-state quantum sensors are present in the base body. Therefore, the difference between the base body and the sensor layer can be seen in the fact that, during the production of the solid immersion lens, solid-state quantum sensors are only actively implanted or otherwise provided in the sensor layer, but not in the base body.

As a result, the emission of light from the solid-state quantum sensors can be limited to the sensor layer. This results in the base body not emitting any light that could interfere with the wide-field microscopy of the solid-state quantum sensors in the sensor layer. Therefore, no spatial resolution along the optical axis is necessary, as is possible with confocal microscopy-imaging using wide-field microscopy is thus possible.

The sensor layer optionally has a thickness that is less than 10%, less than 5%, less than 1%, less than 0.5%, less than 0.3%, less than 0.1%, less than 0.05%, less than 0.01%, less than 0.0001%, or more than 0.00001% of the thickness of the total solid immersion lens. The respective thicknesses can be measured in a z-direction that corresponds to an optical axis of the solid immersion lens and/or the microscope, for example an optical axis of the objective. The sensor layer can extend in an x-y direction that is perpendicular to the z-direction.

Solid-state quantum sensors can be vacancies in the material of the sensor layer, which can optionally be filled with atoms of another material, such as nitrogen vacancies in diamond. Alternatively, solid-state quantum sensors can be atoms at inter-lattice sites. Optionally, solid-state quantum sensors are characterized by the fact that they absorb light in one or more wavelength ranges and/or emit light in a wavelength range different from the absorption wavelength range. A wavelength range can have a size of 10 nm, 20 nm, 30 nm, 40 nm, 50 nm or 100 nm. When light is emitted in a different wavelength range than is absorbed, this is often referred to as fluorescence.

Furthermore, this behavior of solid-state quantum sensors depends on a physical variable at the location of the respective solid-state quantum sensor. This may mean that, depending on the strength, orientation and/or frequency of the physical variable, the solid-state quantum sensors absorb and/or emit light differently. In other words, the physical variable, for example a magnetic field, an electric field or the local temperature, changes the absorption and/or emission of light by the solid-state quantum sensors, optionally depending on the respective wavelength range. This can involve shifting the wavelength range of absorption and/or emission by the physical variable, so that in a selected wavelength range the absorption and/or emission of the solid-state quantum sensors changes, depending on the physical variable.

This change in the absorption and/or emission of the solid-state quantum sensors can be optically imaged with spatial resolution using the wide-field microscope. For example, solid-state quantum sensors begin to absorb and/or emit light when there is a (local) change in the physical variable, and/or they show a change in the strength of the emission and/or absorption. This can be registered in the imaging of solid-state quantum sensors and converted into a change in the physical variable. Since there is a plurality of solid-state quantum sensors present in the sensor layer and wide-field microscopy makes it possible to image the plurality of solid-state quantum sensors, the change in the physical variable can be determined with spatial resolution.

The change in the absorption and/or emission of light by the solid-state quantum sensors can also depend on the orientation of the solid-state quantum sensors relative to the physical variable, for example the orientation of the magnetic or electric field. The solid-state quantum sensors can be implanted or incorporated into the sensor layer in various orientations. In this case, the orientation of the physical variable and/or the change in the orientation of the physical variable can also be determined with spatial resolution using solid-state quantum sensors.

The incorporation or implantation of solid-state quantum sensors can be done statistically randomly, so that the number of solid-state quantum sensors in the sensor layer can be determined via an average density. However, it is also possible to selectively incorporate or implant the solid-state quantum sensors, i.e., at predetermined positions and/or with a predetermined orientation. In the first case, incorporation or implantation is simpler, whereas the second embodiment allows for higher precision in measurement.

In an optional embodiment the sensor layer has a thickness of less than 50 nm, 100 nm, 150 nm, 200 nm, or 300 nm or more than 1 nm.

As described above, the thickness can extend parallel to the optical axis of the wide-field microscope. The solid immersion lens can have a maximum diameter perpendicular to the thickness and/or the optical axis, which is between 0.1 mm and 15 mm, optionally between 0.2 mm and 10 mm, and further optionally between 1 mm and 8 mm. The maximum diameter is the largest diameter of all diameters that can be measured perpendicular to the optical axis of the solid immersion lens or microscope. In the case of a hemispherical solid immersion lens, the maximum diameter corresponds to the diameter. Thus, the maximum diameter of the field of view for imaging solid-state quantum sensors can also be several tens of micrometers.

The thickness of the solid immersion lens, for example along the optical axis of the solid immersion lens or the microscope, can be between 0.1 mm and 10 mm, optionally between 0.2 mm and 5 mm, and further optionally between 0.5 mm and 4 mm.

The field of view or visual field may be limited to a few tens of micrometers due to the (high) refractive index of the solid immersion lens. Therefore, only a section of the sensor layer can be imaged using the wide-field microscope. The field of view is optionally located in the geometric center of the sensor layer. For example, in the case of a hemispherical solid immersion lens, the field of view can be located around the center of the hemisphere.

In an optional embodiment, the solid immersion lens comprises diamond, wherein the solid-state quantum sensors optionally are defects in the crystal lattice, in particular nitrogen vacancy centers. Optionally, the sensor layer and the base body are made of a single-crystal diamond.

In an alternative optional embodiment, the solid immersion lens comprises a semiconductor material, preferably silicon carbide or silicon, wherein the solid-state quantum sensors are further preferably defects in the crystal.

The resolving power of a microscope is limited by the Abbe limit, defined as:

$$d = \frac{λ}{2 * N A}$$

where d is the achievable resolution, A the measured wavelength, and NA is the numerical aperture of the optical system (the numerical aperture of the system can refer to the interaction of the numerical apertures of the solid immersion lens and the wide-field microscope). In the case of measuring the physical variable using NV centers, the optical resolution is thus defined by the measured emission wavelength of the NV center (for example in the wavelength range 637-900 nm, where the main component may be at 700 nm) and the NA. Wide-field NV microscopes typically use optics with an NA of 1.0, which consequently limits the optical resolution to approximately 350 nm (at an emission wavelength of 700 nm). A solid immersion lens (SIL) made of diamond increases the numerical aperture of the optical system because it fills the object space with a solid with a high refractive index. Solid immersion lenses were originally developed to improve spatial resolution in optical microscopy.

In an optional embodiment, the solid immersion lens is a hemisphere with flat bottom, with the sensor layer optionally extending along the flat bottom.

In an alternative optional embodiment, the solid immersion lens is a hemisphere with a conical tip, a supersphere with a conical tip, or a diffraction-based solid immersion lens.

The hemispherical shape, the supersphere, or the diffraction-based shape of the solid-state inversion lens can here be provided by the base body. All of the aforementioned forms can have the effect that the light emitted by the solid-state quantum sensors in the field of view strikes the optical side at such an angle that no or almost no total internal reflection occurs. For example, an angle between a tangent on the optical side and the light emitted by solid-state quantum sensors in the field of view is 90° or essentially 90°. As previously described, this has the effect that essentially all the light emitted by solid-state quantum sensors in the field of view is coupled out from the solid immersion lens.

As mentioned, there are several types of solid immersion lenses (SILs), two of which will be explained in more detail here:
Hemispherical SIL (for example, a hemisphere or spherical segment as the shape for the base body): This is theoretically able to increase the numerical aperture of an optical system by n (n is the refractive index of the lens material=~2.4). Thus, a measurement resolution of 60 nm to 145 nm can be achieved.
Weierstrass SIL (superhemispheric SIL or superSIL): increases the numerical aperture of an optical system by n² (=~5.8). Consequently, significantly better optical resolutions can be achieved when the NV centers are embedded in such a solid immersion lens. In the case of a Weierstrass SIL: a resolution of approximately 60 nm at an emission wavelength of 700 nm.

The sensor layer can extend along the flat bottom of the hemisphere or along the conical tip of the supersphere. Instead of a hemisphere, a spherical segment can also be used.

An objective of the wide-field microscope, located adjacent to the solid immersion lens, can have a concave front face that is opposite the optical side of the solid immersion lens. Due to the convex shapes of the optical side of the solid immersion lens and the concave front of the lens, the front of the lens can extend parallel to the optical side of the solid immersion lens, at least in some areas. This makes it possible to avoid total internal reflection at the two interfaces.

In an optional embodiment, the density of the solid-state quantum sensors in the sensor layer is greater than 0.01 ppm (parts per million), 0.1 ppm, 0.5 ppm, 1 ppm, 2 ppm, or 3 ppm, and/or the density of the solid-state quantum sensors in the substrate is less than 0.1 ppb (parts per billion), 1 ppb, 10 ppb, 50 ppb, 100 ppb, 150 ppb, or 200 ppb. 0.1 ppb corresponds approximately to one-tenth of the “natural” NV concentration, i.e., the NV concentration of the sensor layer.

As explained above, the different densities of the solid-state quantum sensors in the sensor layer and in the base body can be generated by implanting the solid-state quantum sensors only in the sensor layer and not in the base body. The upper limit of the density of solid-state quantum sensors in the base body, listed above, can therefore represent a process artifact. For example, the maximum density of the solid-state quantum sensors in the base body given above indicates the number of vacancies present in the single-crystal material of the base body, even though great importance was placed on avoiding vacancies.

In an optional embodiment, the base body is produced by growing it onto a substrate, in particular iridium or sapphire.

Thus, in a first step, the base body can be grown on a substrate in order to produce a material for the base body that is as much a single-crystal (ideal) lattice structure as possible and/or free of solid-state quantum sensors, for example free of vacancies or atomic interstitial sites. For example, a single-crystal structure of the base body can be produced by growing it on the substrate. Following this, the sensor layer can be grown onto the substrate. In this case, less care can be taken with regard to the unintentional incorporation of vacancies that could serve as quantum sensors, in order to achieve the higher density of solid-state quantum sensors in the sensor layer.

For example, the growth of the base body and/or the sensor layer can be carried out using (homoepitaxial) chemical vapor deposition. In the case of a solid immersion lens made of diamond, the nitrogen concentration can be chosen differently during the growth of the base body and the sensor layer in order to achieve the appropriate concentrations for the solid-state quantum sensors in the respective areas. Of course, other methods are also possible for growing layers, for example physical vapor deposition.

The choice of substrate material for growing the base body can influence the growth direction of the ideal crystallographic orientation. For diamond, the substrate made of iridium or sapphire has therefore proven to be particularly advantageous, namely in that the crystallographic orientation of the unit cell of the diamond on the sample side has a small error angle between the normal on the sample side and the <100>, <111>, <110>, or <113> crystal orientation. It should be noted that the crystal orientation in the sensor layer and in the base body can be identical, and thus the crystal orientation in the sensor layer is also influenced by the substrate unless intermediate steps, as described below, are used.

Separating the growth steps for growing the base body and the sensor layer allows several solid immersion lenses to be produced “in advance” and the sensor layer to be grown subsequently. This allows for significantly faster and more cost-effective production of variations of solid-state quantum sensors on the same base body, i.e., variations of the solid immersion lens with the same geometric shape (since this is determined by the base body).

In an optional embodiment, the base body has a natural concentration of ¹³C isotopes, and optionally the sensor layer has a concentration of ¹³C isotopes that is lower than the natural concentration.

The natural concentration of ¹³C isotopes can be 1.1%, ¹³C isotopes can influence the function of solid-state quantum sensors, for example, their absorption and/or emission behavior. Therefore, in this optional embodiment, the concentration of the ¹³C isotopes in the sensor layer is reduced compared to the base body in order to reduce any potential negative effects of the ¹³C isotopes on the solid-state quantum sensors. Since high-purity carbon, i.e., carbon with a lower concentration of ¹³C isotopes compared to natural carbon, is expensive, the optional embodiment described here has the advantage that this expensive material only needs to be used for the sensor layer, but not for the base body. Furthermore, in the event of a defect, the optional embodiment is significantly less problematic compared to an embodiment in which the sensor layer and the base body are produced in one step. For example, if a defect occurs during the fabrication of the base body, no expensive isotopically pure (<1.1% ¹³C) material has yet been used for the sensor layer.

In an optional embodiment, after the base body has been produced, one side of the base body is ground such that a normal to the ground side has a deviation of less than 1°, 3°, 5°, or 7° or more than 0.1° from a crystal orientation. Optionally, the sensor layer is grown or applied to the ground side.

The grinding of the base body can be carried out in such a way that the ground side of the base body has a roughness of less than 1 nm to 5 nm. The sensor layer can then be grown onto the polished side.

As previously described, the crystal growth of the base body can be influenced by the substrate and other factors, so that a deviation of the crystallographic orientation from a desired orientation may occur. It was found that such a deviation, for example a deviation of more than 1°, negatively affects the functioning of solid-state quantum sensors. For example, solid-state quantum sensors absorb and/or emit less strongly compared to an ideal crystallographic orientation of the lattice structure of the sensor layer. It has been shown that when the sample side has a <100>, <111>, <110>, or <113> crystal orientation, the solid-state quantum sensors exhibit increased or maximum absorption and/or emission.

To ensure such behavior of the solid-state quantum sensors independent of the growth of the substrate, the grown base body can be ground in such a way that the ground side of the base body has the desired crystallographic orientation. Since the sensor layer can be grown directly onto the base body, the sample side also has this desired crystallographic orientation.

After the sensor layer has grown onto the base body, the sensor layer can be further processed in a subsequent step to convert more nitrogen into NV centers; e.g., by electron irradiation, laser irradiation, proton irradiation, etc. This allows the density of the solid-state quantum sensors to be increased independently of the sensor layer's production, compared to the density of the solid-state quantum sensors in the base body. It is also possible that no solid-state quantum sensors are provided during the growth of the sensor layer and that the solid-state quantum sensors are only implanted into the sensor layer after the sensor layer has been grown.

Furthermore, it is also possible that the production of the solid immersion lens takes place in one step, i.e., no distinction is made in the production of the base body and the sensor layer. Here too, the solid-state quantum sensors can be implanted into a layer after the production of the solid immersion lens in order to produce the sensor layer. Thus, a method for producing a solid immersion lens which has solid-state quantum sensors can comprise: producing one of the solid immersion lenses and implanting solid-state quantum sensors in a layer of the solid immersion lens to produce a sensor layer, wherein the density of the solid-state quantum sensors in the sensor layer is greater than the density of the solid-state quantum sensors in the rest of the solid immersion lens (which may correspond to the base body).

Prior to implanting the solid-state quantum sensors, the solid immersion lens can optionally be polished and/or the solid immersion lens can be trimmed or ground such that a normal to the ground or trimmed side has a deviation of less than 1°, 3°, 5°, or 7° or more than 0.1° from a crystal orientation.

In an optional embodiment, the wide-field microscope comprises a lens and/or an image sensor. Using the lens (and optional additional lenses or lens systems), the solid-state quantum sensors can be imaged onto the image sensor via wide-field imaging. The wide-field microscope can be free of a pinhole, such as those used for confocal microscopy to reduce the image in the direction of the optical axis. The wide-field microscope can also comprise optical filters and/or other optical elements to influence, align, focus and/or redirect the beam path.

Here, an image sensor is understood to be a device for capturing two-dimensional images from light by electrical or mechanical means. Semiconductor-based image sensors can be used that can capture light up to the mid-infrared range. Examples of image sensors in the visible and near-infrared range are CCD sensors. The image sensor can convert incident light into electrical or electronic signals, wherein the electrical and electronic signals indicate the intensity of the incident light and/or the wavelength of the incident light, in particular with spatial resolution. For example, the image sensor comprises a plurality of pixels which each generate electrical and electronic signals, wherein the electrical and electronic signals indicate the intensity of the incident light and/or the wavelength of the incident light. The plurality of electrical and electronic signals generated by the pixels can then be converted into a two-dimensional image.

The image sensor can have a number of pixels of 50×50 pixels; 250×250 pixels; 1000×1000 pixels; 2000×2000 pixels, 4000×4000 pixels or 8192×8192 pixels. The image sensor can be non-square and have one of the above-mentioned values for the number of pixels along one direction. The image sensor size is optionally 1×1 μm², 2.5×2.5 μm², 5×5 μm², 10×10 μm², 25×25 μm² or 50×50 μm². As mentioned, the image sensor can also be non-square and then have an edge length with the values mentioned.

The device can also comprise a computer or calculator that communicates with the image sensor. The computer can read the electrical or electronic signals generated by the image sensor, convert them into a digital image and/or calculate an image of the physical variable from the digital image. This can be done, for example, by the computer executing a program or algorithm that converts the intensity and/or wavelength captured by the image sensor for each pixel into the physical variable. For example, the program or algorithm can be fed with information that links a relationship between the intensity and/or wavelength of the light captured by the image sensor and the physical variable. Such relationships are known and describe the physical behavior of solid-state quantum sensors. The computer can therefore perform the step of determining the spatially resolved physical sample based on the solid-state quantum sensor diagram in the method for spatially resolved measurement of a physical variable of a sample.

The device can also comprise a screen which is in data communication with the computer. The computer can control the screen to display the physical variable it has calculated on the screen.

Furthermore, the computer can be in data communication with the light source in order to control the light source. The light source can comprise one or more lasers, one or more LEDs (Light Emitting Diodes) and/or light sources with a broadband emission spectrum. The light source can generate light of a single wavelength or a narrow wavelength spectrum (for example, 10 nm, 20 nm, 50 nm or 100 nm), optionally matching the wavelength or wavelength range generated by the light source to a wavelength range absorbed by solid-state quantum sensors.

The wide-field microscope optionally features a dichroic mirror, which can be used to couple in the light generated by the light source or to couple out the light emitted by the solid-state quantum sensors. Such structures are well known.

In an optional embodiment, the device further comprises a magnetic device for generating a magnetic field gradient in the sensor layer.

The magnetic device can be in data communication with the computer, allowing the computer to control the magnetic device. The magnetic device can generate a magnetic field with a gradient in the sensor layer of the solid immersion lens. The magnetic field generated by the magnetic device can be used to increase or manipulate the absorption and/or emission of the solid-state quantum sensors in order to produce a better signal-to-noise ratio. The magnetic field device can have one or more Helmholtz coils. In this case, the solid immersion lens can be arranged on an axis of the Helmholtz coil.

Alternatively or additionally, the device can comprise a device for generating microwave radiation (e.g., a generator and antenna for emitting microwave radiation) which can be in data communication with the computer, so that the computer can control the device for generating the microwave radiation. Microwave radiation can be used to generate a resonance in solid-state quantum sensors to stimulate absorption and/or emission of light, which can then be optically imaged as described above. For example, solid-state quantum sensors can take advantage of Zeeman splitting. The optimal response of the spin-dependent fluorescence signal (photoluminescence, PL) to a magnetic field can be achieved by setting a microwave driver frequency to the maximum slope of a given ESR dip.

In an optional embodiment, the device comprises a confocal microscope for imaging the solid-state quantum sensors, wherein the confocal microscope can be a STED (Stimulated Emission Depletion) microscope or a STOM (Stochastic Optical Reconstruction Microscope).

The confocal microscope can be used to increase the spatial resolution of the device. For example, the wide-field microscope can be used to generate a complete image of the physical variable, and the confocal microscope can be used to image partial areas of the overall image with a higher resolution.

The beam path of the confocal microscope can be coupled into and/or coupled out of the beam path of the wide-field microscope using beam splitters such as dichroic mirrors. It is also possible that the wide-field microscope images the solid immersion lens from one side and the confocal microscope from another side.

In an optional embodiment, the device further comprises a holder for the solid immersion lens. The holder can be a plate with a hole into which the solid immersion lens is embedded. The surface of the holder can form a plane with the sample side of the solid immersion lens. The sample can be placed on the holder and/or the solid immersion lens.

The device for generating microwave radiation and/or the magnetic device can be arranged on the holder and/or surround the hole or the solid immersion lens.

An exemplary production process for an NV-doped solid immersion lens proceeds as follows:
Growth of a high-purity diamond substrate (<50 ppm nitrogen concentration) to produce the base body.
Polishing of the diamond substrate in spherical form
Cutting the diamond sphere, for example along the crystal direction (<100>, <111>, or <110>) to form a hemisphere or Weierstrass SIL.
Implanting nitrogen atoms into the hemisphere to form NV centers or overgrowing a nitrogen-doped diamond layer on the flat side (sample side) of the solid immersion lens by chemical vapor deposition to create the sensor layer.

An exemplary method in which the growth and production steps are separated in time proceeds as follows:
A macroscopic solid immersion lens is made from CVD (Chemical Vapor Deposition) diamonds. This SIL usually has a millimeter size (0.5-4.0 mm radius, typically 1.0 mm radius). The diamond material can here contain ~1.1% 13C (natural 13C isotope concentration) and ideally has a nitrogen concentration of <1-200 ppb. However, the nitrogen concentration can also be higher if measured in a confocal fluorescence microscope.
The flat side of the SIL is polished to a roughness of <1-5 nm and must be corrected to <1° error angle from the ideal crystallographic orientation. We found that diamond material grown on the solid immersion lens with >1° misalignment using CVD produces inferior NV center properties. The flat side of the SIL has a <100>, <111>, <110>, or <113> crystal orientation.
Subsequently, a second diamond layer (the sensor layer) is grown on the flat side of the solid immersion lens using homoepitaxial CVD. This diamond layer has a defined nitrogen concentration in the ppb to ppm range, ideally but not necessarily has <1.1% 13C content and is nanometer to micrometer thick. During this growth step, some nitrogen atoms are already converted into NV centers.
The sensor layer of the solid immersion lens can be further treated in the subsequent step to convert more nitrogen into NV centers; e.g., by electron irradiation, laser irradiation, proton irradiation, etc.

A wide variety of different embodiments are possible, in which the following parameters can be varied:
Geometry of the solid immersion lens: various geometries are known, e.g.: hemispherical SIL, Weierstrass SIL, . . . .
Different sizes of the solid immersion lens
Different nitrogen concentrations in the material of the solid immersion lens, in particular the sensor layer
Different crystal orientations of the flat side or sample side of the solid immersion lens
Different sensor layer thicknesses from nm to μm
Different nitrogen concentrations in the sensor layer
Different quantum sensors based on a wide variety of diamond color centers

The invention can also be summarized by the following aspects:

Aspect 1: A method for producing a macroscopic quantum sensor-doped solid immersion lens, comprising:

Producing a solid immersion lens made of single-crystal diamond with a nitrogen concentration <1-200 ppb and an error angle (deviating from the ideal crystal orientation) of <1° and

Subsequent growth of a second diamond layer containing quantum sensors.

Aspect 2: A method according to aspect 1, according to which the solid immersion lens has a radius of 0.5-4.0 mm.

Aspect 3: A method according to aspect 1, according to which the solid immersion lens contains 1.1% 13C.

Aspect 4: A method according to aspect 1, according to which the quantum sensor-doped diamond layer contains 1.1% 13C or less.

Aspect 5: A method according to aspect 1, according to which the crystallographic orientation of the flat side of the solid immersion lens corresponds to <100>, <111>, <110>, or <113>.

Aspect 6: A method according to aspect 1, according to which the quantum sensors are diamond color centers.

Aspect 7: A method according to aspect 1, according to which the quantum sensors are nitrogen or silicon vacancy centers.

The invention can also be summarized by the following aspects:

Aspect 1: A method for microscopy of magnetic fields with increased optical resolution using solid immersion lenses, which are doped with an ensemble of solid-state quantum sensors.

Aspect 2: Method according to aspect 1, wherein the solid immersion lens consists of a semiconductor material.

Aspect 3: Method according to aspect 1 or 2, wherein the solid immersion lens consists of diamond.

Aspect 4: Method according to aspect 3, wherein the solid-state quantum sensors are nitrogen vacancy centers.

Aspect 5: Method according to aspect 3, wherein the solid-state quantum sensors are nitrogen vacancy centers.

Aspect 6: Method according to aspect 1, wherein the solid immersion lens is a hemisphere with flat bottom.

Aspect 7: Method according to aspect 1, wherein the solid immersion lens is a supersphere (Weierstrass) with flat bottom.

Aspect 8: Method according to aspect 1, wherein the solid immersion lens is a hemisphere with a conical tip.

Aspect 9: Method according to aspect 1, wherein the solid immersion lens is a supersphere with a conical tip.

Aspect 10: Method according to aspect 1, wherein the solid immersion lens is a refraction-based solid immersion lens.

Aspect 11: Method according to aspect, wherein magnetic field gradients are used to improve the resolution.

Aspect 12: Method according to aspect 1, wherein the method is combined with other methods for resolution improvement (e.g. STED, STORM, . . . ).

The invention will now be explained with reference to the attached drawings. The drawings show:

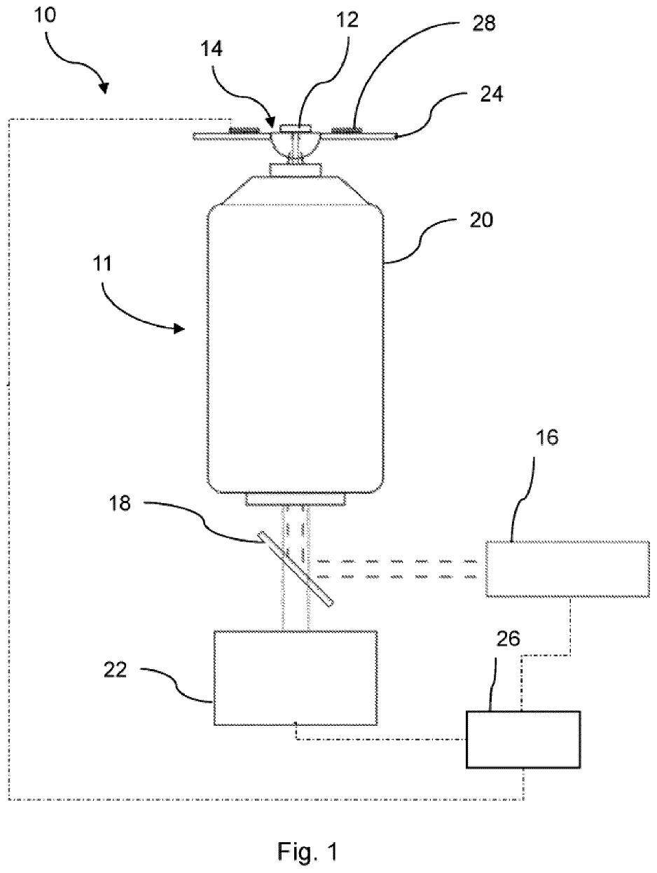

FIG. 1 a schematic view of the setup of a device for a spatially resolved measurement of a physical variable of a sample according to a first embodiment;

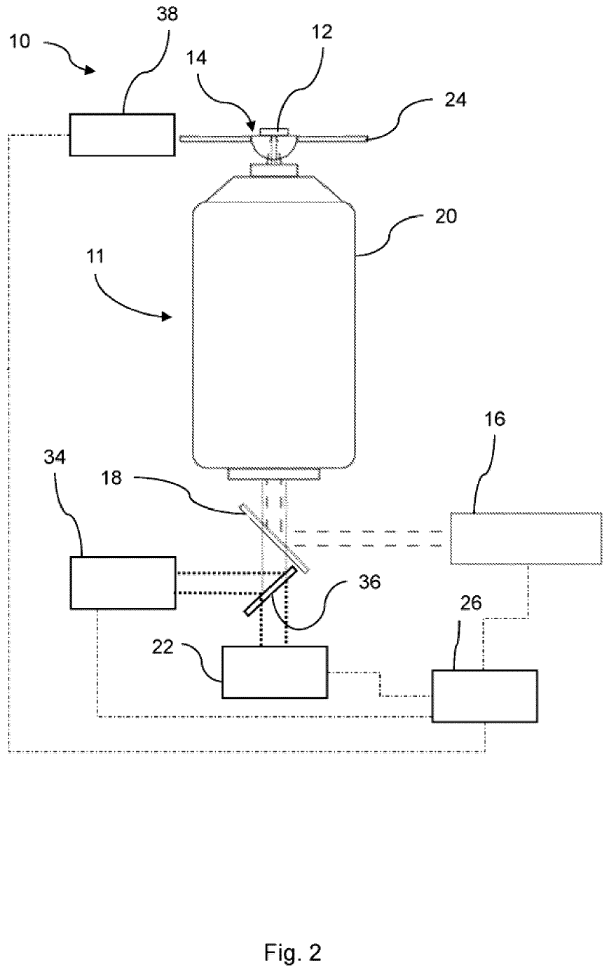

FIG. 2 a schematic view of the setup of a device for a spatially resolved measurement of a physical variable of a sample according to a first embodiment;

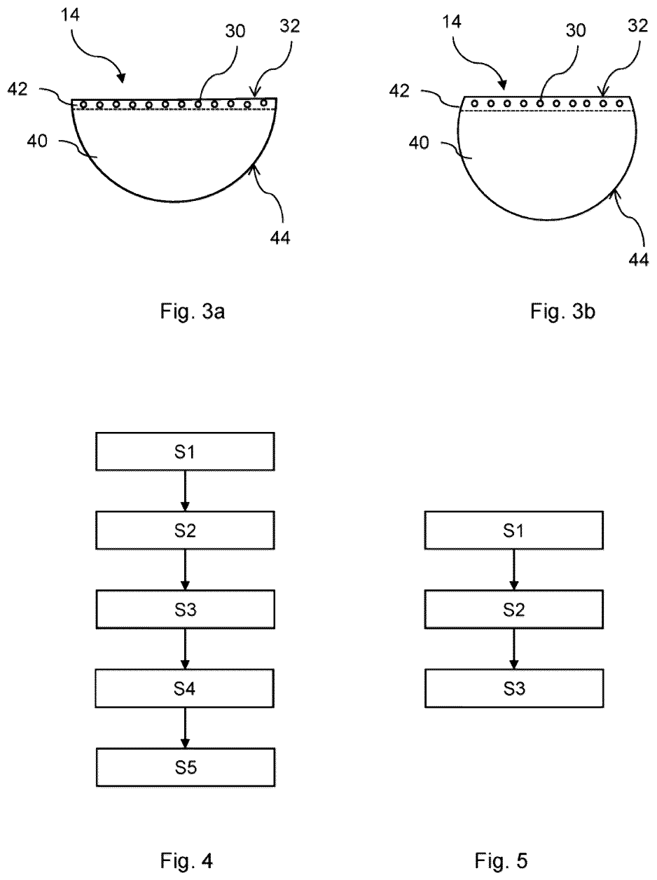

FIGS. 3a and 3b schematic cross-sections of two embodiments of a solid immersion lens which can be used for the devices according to FIG. 1 or 2;

FIG. 4 a block diagram for a method for producing the solid immersion lens according to FIG. 3a or 3b; and

FIG. 5 a block diagram for a method for spatially resolved measurement of a magnetic field of a sample.

FIG. 1 shows a first embodiment of a device 10 for a spatially resolved measurement of a physical variable of a sample 12. The physical variable can be a magnetic field or an electric field that is generated or varied by the sample 12.

The device 10 comprises a wide-field microscope 11, a solid immersion lens 14 and/or a light source 16. The wide-field microscope 11 comprises a beam splitter 18, a lens 20, an image sensor 22 and/or a holder 24. The device 10 can further comprise a computer 26 and/or a microwave antenna 28 as an example of a device for generating microwave radiation.

The solid immersion lens 14 has a plurality of solid-state quantum sensors 30 (see FIG. 3) which can be imaged onto the image sensor 22 by means of the lens 20. In other words, the wide-field microscope 11 allows the solid-state quantum sensors 30 to be imaged onto the image sensor 22 using a wide-field imaging technique. The image sensor 22 converts the incident light radiation into electrical or electronic signals with spatial resolution. For example, the image sensor 22 comprises a plurality of pixels, with each pixel generating an electrical or electronic signal that specifies an intensity and/or wavelength of the incident radiation for each pixel. From the plurality of electrical or electronic signals for each pixel, a digital image of the solid-state quantum sensors 30 in the solid immersion lens 14 can thus be generated. This can be done by the computer 26, which is in data communication with the image sensor 22, for example to trigger the electrical or electronic signals of the image sensor 22 and/or to control the image sensor 22.

The computer 26, for example, has a processor and memory. The memory can store one or more programs and/or algorithms that are executed by the processor. Furthermore, the computer 26 can be in data communication with the light source 16 in order to control the light source 16. The light source 16 can comprise one or more lasers or other devices for generating light. The light produced by the light source 16 can be in the visible wavelength range, the infrared wavelength range or the ultraviolet wavelength range. The light source 16 can be configured to selectively generate light in a selected wavelength range, for example in a wavelength range that is absorbed by the solid-state quantum sensors 30.

The light generated by the light source 16 is coupled to the wide-field microscope 11 via the beam splitter 18 and directed to the lens 20. The lens 20 focuses the incident light onto the solid-state quantum sensors 30 in the solid immersion lens 14. The light emitted by the solid-state quantum sensors 30 and/or light that is reflected, for example, at the interface between the solid immersion lens 14 and the sample 12 and in which light of one or more wavelengths is absorbed by the solid-state quantum sensors 30 (so that the intensity of the reflected light varies depending on location and/or wavelength) is projected by the lens 20 onto the image sensor 22. The light rays in the beam paths described here do not have to be parallel, as shown in FIG. 1.

The beam splitter 18 can be a semitransparent mirror and/or a dichroic mirror. The choice of the type of beam splitter 18 depends on the light produced by the light source 16 and which light is emitted and/or absorbed by the solid-state quantum sensors 30.

The solid immersion lens 14 is supported by the holder 24. The holder 24, for example, has a hole into which the solid immersion lens 14 is inserted. The surface of the holder 24 can form a plane with the sample side 32 of the solid immersion lens 14. The sample 12 can be placed on the solid immersion lens 14 and/or the holder 24.

The holder 24 can also support the microwave antenna 28. The microwave antenna 28 can surround the solid immersion lens 14, so that the microwave radiation emitted by the antenna 28 penetrates the solid immersion lens 14 from all sides and interacts with the solid-state quantum sensors 30. The microwave antenna 28 can be controlled by the computer 26 and/or is in data communication with the computer 26. The microwave radiation generated by the microwave antenna 28 can be used to stimulate and/or increase the absorption and/or emission of light by the solid-state quantum sensors 30.

FIG. 2 shows a second embodiment of a device 10 for a spatially resolved measurement of a physical variable of a sample 12, which, apart from the differences described below, has the same optional features, properties, and/or components as the device 10 described in FIG. 1.

The device 10 according to FIG. 2 does not comprise a microwave antenna 28, but instead a confocal microscope 34, a second beam splitter 36 and/or a magnetic device 38. The confocal microscope 34 can be coupled into the beam path of the wide-field microscope 11 via the second beam splitter 36. The beam splitter 36 can be a semitransparent mirror and/or a dichroic mirror. The confocal microscope 34 can be constructed like a known confocal microscope and/or have a pinhole to image a selected layer in the solid immersion lens 14. This allows background radiation to be suppressed better compared to a wide-field image. The solid-state quantum sensors 30 are optionally located in the layer imaged by the confocal microscope 34. The confocal microscope 34 can also be used to achieve a higher spatial resolution.

The magnetic device 38 can be in data communication with he computer 26 and/or controlled by the computer 26. The magnetic device 38 can generate a magnetic field, in particular a magnetic field gradient along the solid-state quantum sensors 30 in the solid immersion lens 14. The magnetic field generated by the magnetic device 38 can be used to enable and/or enhance the absorption and/or emission of light by the solid-state quantum sensors 30.

The solid immersion lens 14 according to FIG. 3a has the geometric shape of a hemisphere and is made of diamond. The solid immersion lens 14 can be divided into a base body 40 and a sensor layer 42, and the solid immersion lens 14 also forms a single-level component. The sensor layer 42 and the base body 40 can differ in that the solid-state quantum sensors 30 are only provided in the sensor layer 42. This can be understood to mean that the solid-state quantum sensors 30 are merely implanted or inserted into the sensor layer 42, whereas this does not happen with the base body 40. However, solid-state quantum sensors 30 can also be present in the base body 40, namely due to artifacts such as lattice misalignments or vacancies in the lattice structure of the base body 40. Generally speaking, the density of the solid-state quantum sensors 30 in the sensor layer 42 is higher than the density of the solid-state quantum sensors in the base body 40. For example, the density of the solid-state quantum sensors 30 in the sensor layer 42 is greater than 0.01 ppm, 0.1 ppm, 0.5 ppm, 1 ppm, 2 ppm, or 3 ppm, and/or the density of the solid-state quantum sensors 30 in the base body 40 is less than 0.1 ppb, 1 ppb, 10 ppb, 50 ppb, 100 ppb, 150 ppb, or 200 ppb.

The solid immersion lens 14 has a size on the order of millimeters (for example, 0.5-4.0 mm radius, optionally 1.0 mm radius). In an optional embodiment the sensor layer 42 has a thickness of less than 50 nm, 100 nm, 150 nm, 200 nm, or 300 nm or more than 1 nm.

The solid immersion lens 14 has the sample side 32, which is defined by the flat bottom of the hemispherical shape, and an optical side 44, which is defined by the hemispherical shape. The optical side 44 is arranged facing the lens 20, while the sample side 32 faces the sample 12 or is in contact with the sample 12. The sensor layer 42 extends along the sample side 32. This means that the solid-state quantum sensors 30 are arranged only along the sample side 32.

The solid immersion lens 14 is made of diamond and the solid-state quantum sensors 30 are defects in the crystal lattice, in particular nitrogen vacancy centers. The base body 40 has a natural concentration of ¹³C isotopes, while the sensor layer 42 has a concentration of ¹³C isotopes that is lower than the natural concentration.

Alternatively, the solid immersion lens 14 can comprise a semiconductor material, preferably silicon carbide or silicon. In this case, the solid-state quantum sensors 30 could have defects in the crystal.

The solid immersion lens 14 according to FIG. 3b has the same optional features, properties, and/or materials as the solid immersion lens 14 described in FIG. 3a, except for the differences described below. The difference between the two solid immersion lenses 14 is that the solid immersion lens 14 according to FIG. 3b has the shape of a spherical segment.

The following describes a method for producing a solid immersion lens 14. In step S1, a substrate is provided, for example iridium or sapphire. In step S2, the basic body 40 is grown onto the substrate. This can be done using chemical vapor deposition. In the process, the nitrogen concentration is kept low in order to achieve the density of the solid-state quantum sensors 30 in the base body 40 described above. Furthermore, natural carbon can be used for the base body 40, i.e., with a natural concentration of ¹³C isotopes.

In step S3 the base body 40 is ground such that a normal to the ground side has a deviation of less than 1°, 3°, 5°, or 7° or more than 0.1° from a crystal orientation. The crystal orientation can refer to the <100>, <111>, <110> or <113> axis of the lattice structure of diamond. In step S4, the sensor layer 42 is grown onto the ground side of the base body 40. This can also be done by chemical vapor deposition, wherein the nitrogen concentration may be elevated compared to the production of the base body 40 in order to provide the higher density of solid-state quantum sensors 30 in the sensor layer 42. Furthermore, carbon can be used for the sensor layer 42, which has a lower concentration than the natural concentration of ¹³C isotopes.

In an otherwise optional step S5, the sensor layer 42 can be further treated to convert more nitrogen into NV centers; e.g., by electron irradiation, laser irradiation, proton irradiation, etc.

The following describes a method for spatially resolved measurement of a magnetic field of the sample 12. In step S1, the solid immersion lens 14 is placed in the wide-field microscope 11 and the sample 12 is placed on the solid immersion lens 14. In step S2, the solid immersion lens 14 is illuminated by the light source 16 in such a way that the solid quantum sensors 30 interact with the light generated by the light source 16. Then the lens 20 is adjusted so that the solid-state quantum sensors 30 are imaged onto the image sensor 22. In step S3, the image of the solid-state quantum sensors 30 is recorded and evaluated in order to determine the magnetic field caused by the sample 12 with spatial resolution.

1. A solid immersion lens for a spatially resolved measurement of a physical variable of a sample (12), comprising
a basic body (40),
a sensor layer (42) which is configured to be in contact with the sample (12), and
a plurality of solid-state quantum sensors (30),
wherein the solid-state quantum sensors (30) are configured to absorb and/or emit light differently at the location of the respective solid-state quantum sensor, depending on the physical variable to be measured, and
wherein a density of solid-state quantum sensors (30) in the sensor layer (42) is greater than the density of the solid-state quantum sensors (30) in the base body (40).

2. The solid immersion lens according to claim 1, wherein the sensor layer (42) has a thickness of less than 50 nm, 100 nm, 150 nm, 200 nm or 300 nm, and/or
wherein the density of the solid-state quantum sensors (30) in the sensor layer is greater than 0.01 ppm, 0.1 ppm, 0.5 ppm, 1 ppm, 2 ppm or 3 ppm, and/or
wherein the density of the solid-state quantum sensors (30) in the base body (40) is less than 1 ppb, 10 ppb, 50 ppb, 100 ppb, 150 ppb or 200 ppb.

3. The solid immersion lens according to claim 1 or 2, wherein
the solid immersion lens (14) comprises diamond and the solid-state quantum sensors (30) are optionally defects in the crystal lattice, in particular nitrogen vacancy centers, or
the solid immersion lens (14) comprises a semiconductor material, optionally silicon carbide or silicon, wherein the solid-state quantum sensors (30) are further optionally defects in the crystal.

4. The solid immersion lens according to any one of the preceding claims, wherein
the solid immersion lens (14) is a hemisphere with flat bottom, with the sensor layer (42) extending along the flat bottom, or
the solid immersion lens (14) is a hemisphere with conical tip, a supersphere with conical tip, or a refraction-based solid immersion lens (14).

5. A method for producing a solid immersion lens (14) which comprises solid-state quantum sensors (30), comprising:
producing a base body (40) of the solid immersion lens (14) with a first density of solid-state quantum sensors (30), and
growing a sensor layer (42) onto the base body (40), wherein the sensor layer (42) has a second density of solid-state quantum sensors (30) that is greater than the first density.

6. The method according to claim 5, wherein the base body (40) and the sensor layer (42) comprise diamond, wherein the base body (40) is produced by growing it onto a substrate, in particular iridium or sapphire,
wherein optionally the base body (40) has a natural concentration of ¹³C isotopes, wherein the sensor layer (42) has a concentration of ¹³C isotopes that is lower than the natural concentration.

7. The method according to claim 5 or 6, wherein, after the base body (40) has been produced, one side of the base body (40) is ground such that a normal to the ground side has a deviation of less than 1°, 3°, 5°, or 7° from a crystal orientation, and
wherein the sensor layer (42) is grown onto the ground side.

8. A device for a spatially resolved measurement of a physical variable of a sample (12), comprising
a solid immersion lens (14) with a plurality of solid-state quantum sensors (30), in particular according to any one of claims 1 to 7,
a light source (16) for illuminating the solid-state quantum sensors (30), and
a wide-field microscope (11) for imaging the solid-state quantum sensors (30).

9. The device according to claim 8, further comprising
a magnetic device (38) for generating a magnetic field gradient in the sensor layer (42) and/or
a confocal microscope (34) for imaging the solid-state quantum sensors (30), wherein the confocal microscope (34) optionally is a STED (Stimulated Emission Depletion) microscope or a STOM (Stochastic Optical Reconstruction Microscope).

10. A method for spatially resolved measurement of a physical variable of a sample (12), comprising
placing a solid immersion lens (14) with a plurality of solid-state quantum sensors (30), in particular according to any one of claims 1 to 4,
imaging the solid-state quantum sensors (30) using wide-field microscopy, and
determining the spatially resolved physical variable using the image of the solid-state quantum sensors (30).
